(19) United States
(12) Patent Application Publication
(10) Pub. No.: US 2024/0250166 A1
(43) Pub. Date: Jul. 25, 2024

(54) TRENCH GATE SEMICONDUCTOR DEVICE AND METHOD FOR MANUFACTURING THE SAME

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: Hidemoto TOMITA, Nisshin-shi (JP)

(21) Appl. No.: 18/533,354

(22) Filed: Dec. 8, 2023

(30) Foreign Application Priority Data
Jan. 19, 2023 (JP) 2023-006764

(51) Int. Cl. H01L 29/78; H01L 21/18; H01L 29/10; H01L 29/16; H01L 29/66

(52) U.S. Cl. CPC H01L 29/7813; H01L 21/187; H01L 29/1095; H01L 29/1608; H01L 29/66068

(57) ABSTRACT

A trench gate semiconductor device includes a semiconductor substrate, first and second trenches, a gate insulating film, a gate electrode, and an upper electrode. The semiconductor substrate includes an n-type first semiconductor region in contact with the upper electrode, a p-type body region extending from the gate insulating film in the first trench to the gate insulating film in the second trench below the first semiconductor region, and an n-type second semiconductor region extending from the gate insulating film in the first trench to the gate insulating film in the second trench below the body region. A maximum value of a distance between the first trench and the second trench in a depth range in which the body region is disposed is less than 200 nm. The distance between the first trench and the second trench at the upper surface of the semiconductor substrate is larger than the maximum value.

### CROSS REFERENCE TO RELATED APPLICATION

The present application claims the benefit of priority from Japanese Patent Application No. 2023-006764 filed on Jan. 19, 2023. The entire disclosures of the above application are incorporated herein by reference.

### TECHNICAL FIELD

The present disclosure relates to a trench gate semiconductor device and a method for manufacturing the same.

### BACKGROUND

For example, a trench gate semiconductor device includes a semiconductor substrate having a plurality of trenches provided at intervals on an upper surface thereof, a gate insulating film and a gate electrode disposed in each of the trenches, and an upper electrode covering the upper surface of the semiconductor substrate. The semiconductor substrate includes an n-type source region, a p-type body region, and an n-type drift region. The source region is disposed between the two trenches and is in contact with the upper electrode. The body region is disposed between the two trenches and extends from a position in contact with the gate insulating film in one of the two trenches to a position in contact with the gate insulating film in the other trench. The drift region is disposed between the two trenches below the body region. The drift region is separated from the source region by the body region.

In such a semiconductor device, the distance between two adjacent trenches is relatively small. Thus, when the semiconductor device is turned on, almost entire region of the body region located between the trenches is inverted to form a channel.

### SUMMARY

The present disclosure describes a trench gate semiconductor device and a method for manufacturing the same. According to an aspect of the present disclosure, a trench gate semiconductor device includes a semiconductor substrate, a first trench, a second trench, a gate insulating film, a gate electrode, and an upper electrode. The semiconductor substrate includes an n-type first semiconductor region that is in contact with the upper electrode, a p-type body region that is disposed below the first semiconductor region and extends from a position in contact with the gate insulating film in the first trench to a position in contact with the gate insulating film in the second trench, and an n-type second semiconductor region that is disposed below the body region, and extends from a position in contact with the gate insulating film in the first trench to a position in contact with the gate insulating film in the second trench. A maximum value of a distance between the first trench and the second trench in a depth range in which the body region is disposed is less than 200 nm. The distance between the first trench and the second trench at the upper surface of the semiconductor substrate is larger than the maximum value.

### BRIEF DESCRIPTION OF THE DRAWINGS

Objects, features and advantages of the present disclosure will become more apparent from the following detailed description made with reference to the accompanying drawings, in which like parts are designated by like reference numbers and in which:

FIG. 1 is a cross-sectional view of a trench gate semiconductor device according to an embodiment of the present disclosure;

FIG. 2 is a diagram for explaining a process of manufacturing the trench gate semiconductor device;

FIG. 3 is a diagram for explaining a process of manufacturing the trench gate semiconductor device;

FIG. 4 is a diagram for explaining a process of manufacturing the trench gate semiconductor device;

FIG. 5 is a diagram for explaining a process of manufacturing the trench gate semiconductor device;

FIG. 6 is a diagram for explaining a process of manufacturing the trench gate semiconductor device;

FIG. 7 is a diagram for explaining a process of manufacturing the trench gate semiconductor device;

FIG. 8 is a diagram for explaining a process of manufacturing the trench gate semiconductor device;

FIG. 9 is a diagram for explaining a process of manufacturing the trench gate semiconductor device; and

FIG. 10 is a diagram for explaining a process of manufacturing the trench gate semiconductor device.

### DETAILED DESCRIPTION

To begin with, a relevant technology will be described only for understanding the embodiments of the present disclosure.

There is known a trench gate semiconductor device including a semiconductor substrate having a plurality of trenches provided at intervals on an upper surface thereof, a gate insulating film and a gate electrode disposed in each of the trenches, and an upper electrode covering the upper surface of the semiconductor substrate. The semiconductor substrate includes an n-type source region, a p-type body region, and an n-type drift region. The source region is disposed between the two trenches and is in contact with the upper electrode. The body region is disposed between the two trenches and extends from a position in contact with the gate insulating film in one of the two trenches to a position in contact with the gate insulating film in the other trench. The drift region is disposed between the two trenches below the body region. The drift region is separated from the source region by the body region.

In such a semiconductor device, the distance between two adjacent trenches is relatively small. Thus, when the semiconductor device is turned on, almost entire region of the body region located between the trenches is inverted to form a channel. In the present disclosure, a phenomenon in which almost entire body region functions as a channel when the semiconductor device is turned on is referred to as a FinFET effect. When the FinFET effect occurs, electrons flow even at a position away from the gate insulating film. Therefore, electrons are less likely to be affected by scattering caused by the interface between the gate insulating film and the body region. As a result, the mobility of electrons can be improved, and the channel resistance can be reduced.

In the semiconductor device described above, the channel resistance can be reduced by reducing the distance between two adjacent trenches. On the other hand, since the distance between two adjacent trenches is small, it is difficult to ensure a contact area between the source region and the upper electrode. As such, there is a drawback that the contact resistance is large. The present disclosure provides a technique for reducing both the channel resistance and the contact resistance.

According to an aspect of the present disclosure, a trench gate semiconductor device includes: a semiconductor substrate; a first trench provided in an upper surface of the semiconductor substrate; a second trench provided in the upper surface of the semiconductor substrate and spaced apart from the first trench in a lateral direction; a gate insulating film covering an inner surface of each of the first trench and the second trench; a gate electrode disposed in each of the first trench and the second trench and insulated from the semiconductor substrate by the gate insulating film; and an upper electrode covering the upper surface of the semiconductor substrate. The semiconductor substrate includes: an n-type first semiconductor region that is disposed between the first trench and the second trench and in contact with the upper electrode; a p-type body region that is disposed between the first trench and the second trench below the first semiconductor region and extends from a position in contact with the gate insulating film in the first trench to a position in contact with the gate insulating film in the second trench; and an n-type second semiconductor region that is disposed between the first trench and the second trench below the body region, extends from a position in contact with the gate insulating film in the first trench to a position in contact with the gate insulating film in the second trench, and is separated from the first semiconductor region by the body region. A maximum value of a distance between the first trench and the second trench in the lateral direction in a depth range in which the body region is disposed is less than 200 nm. The distance between the first trench and the second trench at the upper surface of the semiconductor substrate is larger than the maximum value.

In the trench gate semiconductor device, the body region extends from the position in contact with the gate insulating film in the first trench to the position in contact with the gate insulating film in the second trench. In addition, the maximum value of the distance between the first trench and the second trench in the lateral direction in the depth range in which the body region is disposed is less than 200 nm, which is sufficiently small to cause the FinFET effect. Therefore, when the semiconductor device is turned on, a channel is formed in substantially the entire body region.

In the trench gate semiconductor device, the distance between the first trench and the second trench at the upper surface of the semiconductor substrate is larger than the maximum value. Therefore, the contact area between the first semiconductor region and the upper electrode is relatively large. As such, the contact resistance between the first semiconductor region and the upper electrode is small. As described above, in the trench gate semiconductor device, low channel resistance and low contact resistance can be realized.

According to an aspect of the present disclosure, a method for manufacturing a trench gate semiconductor device includes: preparing a first substrate including an n-type first semiconductor region provided on an upper surface of an n-type substrate, a p-type body region provided on an upper surface of the first semiconductor region, and an n-type second semiconductor region provided on an upper surface of the body region; forming an amorphous layer in a vicinity of an upper surface of the second semiconductor region; forming a first trench and a second trench each extending from the upper surface of the second semiconductor region and reaching the first semiconductor region, in which the first trench and the second trench are formed such that a maximum value of a distance between the first trench and the second trench in a lateral direction in a depth range in which the body region is disposed is less than 200 nm, and the distance between the first trench and the second trench at bottoms of the first trench and the second trench is larger than the maximum value; forming a first insulating film covering an inner surface of each of the first trench and an inner surface of the second trench, a gate electrode in each of the first trench and the second trench, and a second insulating film covering an upper surface of the gate electrode in each of the first trench and the second trench; planarizing the upper surface of the second semiconductor region and an upper surface of the second insulating film while remaining the amorphous layer; preparing an n-type second substrate in which an amorphous layer is formed in a vicinity of an upper surface thereof; bonding the first substrate and the second substrate such that the amorphous layer of the first substrate and the amorphous layer of the second substrate face each other; exposing the first semiconductor region and the first insulating film by grinding the first substrate from a side of the n-type substrate; and forming an electrode in contact with the first semiconductor region exposed by the grinding.

In general, it is relatively easy to form a trench in which the width of the lower portion is narrower than that of the upper portion. On the other hand, it is difficult to form a trench in which the width of the lower portion is wider than that of the upper portion. In the manufacturing method described above, the trenches are formed in the first substrate such that the distance between the first trench and the second trench at the bottom portions of the first trench and the second trench is larger than the maximum value of the distance between the first trench and the second trench in the depth range in which the body region is disposed. Then, the upper surface of the second substrate (that is, the surface formed with the amorphous layer in the second substrate) and the trench-formed surface of the first substrate (that is, the surface of the first substrate on the second semiconductor region side) are bonded to each other. That is, the first substrate in which the trench is formed is turned upside down and bonded to the second substrate. Thereafter, the surface of the first substrate opposite to the trench-formed surface (that is, the surface on the first substrate side in the bonded substrate) is ground to expose the first semiconductor region and the first insulating film in each of the first trench and the second trench. Further, an electrode is formed to be in contact with the exposed first semiconductor region. As a result, it is possible to obtain the trenches in which the distance between the first trench and the second trench at the position in contact with the electrode, that is, at the position which was the bottom portions of the first trench and the second trench before the bonding is larger than the maximum value. Therefore, the contact area between the first semiconductor region and the electrode can be ensured. The first trench and the second trench are formed such that the maximum value of the distance is less than 200 nm. Accordingly, the semiconductor device having a low channel resistance due to the FinFET effect and a low contact resistance can be manufactured.

According to an aspect of the present disclosure, in the trench gate semiconductor device described above, the distance between the first trench and the second trench may decrease downward from the upper surface of the semiconductor substrate.

An embodiment of the present disclosure will be described hereinafter in detail with reference to the drawings.

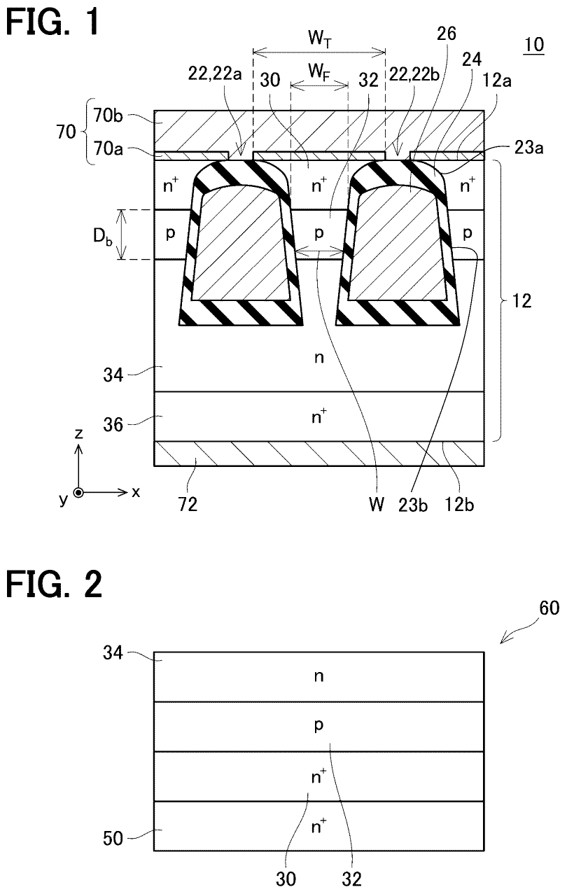

A trench gate semiconductor device 10 (hereinafter, simply referred to as a semiconductor device 10) according to an embodiment shown in FIG. 1 is a metal oxide semiconductor field effect transistor (MOSFET). The semiconductor device 10 includes a semiconductor substrate 12. The semiconductor substrate 12 is made of silicon carbide (SiC). However, the material of the semiconductor substrate 12 is not particularly limited, and may be, for example, silicon (Si), gallium nitride (GaN), diamond, or the like. In the following, a direction parallel to an upper surface 12a of the semiconductor substrate 12 is referred to as an x direction, and a direction parallel to the upper surface 12a and perpendicular to the x direction is referred to as a y direction. Further, a direction perpendicular to the x direction and the y direction is referred to as a z direction. The z direction corresponds to a thickness direction of the semiconductor substrate 12. The x direction corresponds to a lateral direction.

Multiple trenches 22 are provided in the upper surface 12a of the semiconductor substrate 12. Each of the trenches 22 extends long in the y direction. The trenches 22 are arranged parallel to each other at intervals in the x direction. An inner surface of each of the trenches 22 is covered with a gate insulating film 24. A gate electrode 26 is disposed in each of the trenches 22. The gate electrode 26 is made of, for example, polysilicon. The gate insulating film 24 also covers an upper surface of the gate electrode 26. In other words, the gate electrode 26 is surrounded by the gate insulating film 24. The gate electrode 26 is insulated from the semiconductor substrate 12 by the gate insulating film 24. A part of the gate insulating film 24 is exposed on the upper surface 12a of the semiconductor substrate 12. The width of each trench 22, that is, the dimension of each trench 22 in the x direction increases from the upper surface 12a of the semiconductor substrate 12 toward the lower side. Both side surfaces of each trench 22 are inclined away from the center of the trench 22 toward a bottom surface side. More specifically, each of the side surfaces of the trench 22 includes a first side surface portion 23a connecting to the upper surface 12a of the semiconductor substrate 12 and a second side surface portion 23b connecting to a lower end of the first side surface portion 23a. The first side surface portion 23a extends while being slightly curved so as to be convex upward. The second side surface portion 23b extends in a substantially planar shape. An angle defined between the second side surface portion 23b and the upper surface 12a is larger than an angle defined between the first side surface portion 23a and the upper surface 12a. That is, the inclination of the second side surface portion 23b is gentler than that of the first side surface portion 23a. Most of the side surface of the trench 22 is constituted by the second side surface portion 23b. Hereinafter, for convenience of description, the trench 22 on the left side in FIG. 1 will be referred to as a first trench 22a, and the trench 22 on the right side in FIG. 1 will be referred to as a second trench 22b. Although not shown, multiple trenches similar to the trenches 22 are further formed on the left side of the first trench 22a and on the right side of the second trench 22b in FIG. 1.

An upper electrode 70 is disposed on the upper surface 12a of the semiconductor substrate 12. The upper electrode 70 includes a source contact electrode 70a and a source electrode 70b. The source contact electrode 70a is made of, for example, nickel silicide (NiSi), titanium silicide (TiSi), or the like. The source contact electrode 70a is provided in a range where the gate insulating film 24 is not exposed. The source electrode 70b is made of, for example, aluminum silicon (AlSi). The source electrode 70b covers the upper surface of the source contact electrode 70a and the upper surface of the gate insulating film 24. The upper electrode 70 is insulated from the gate electrode 26 by the gate insulating film 24. A lower electrode 72 is disposed on the lower surface 12b of the semiconductor substrate 12. The lower electrode 72 is in contact with substantially the entire region of the lower surface 12b of the semiconductor substrate 12.

The semiconductor substrate 12 is formed with a source region 30, a body region 32, a drift region 34, and a drain region 36.

The source region 30 is an n-type region. The source region 30 is disposed at a position exposed on the upper surface 12a of the semiconductor substrate 12, and is in ohmic contact with the upper electrode 70, that is, the source contact electrode 70a. The source region 30 extends from a position in contact with the gate insulating film 24 in the first trench 22a to a position in contact with the gate insulating film 24 in the second trench 22b. The source region 30 is in contact with the gate insulating film 24 at the upper end portion of the first trench 22a, and the gate insulating film 24 at the upper end portion of the second trench 22b.

The body region 32 is a p-type region. The body region 32 is in contact with the source region 30. The body region 32 extends from a position in contact with the gate insulating film 24 in the first trench 22a to a position in contact with the gate insulating film 24 in the second trench 22b, below the source region 30. The body region 32 is in contact with the gate insulating film 24 in the first trench 22a and the gate insulating film 24 in the second trench 22b, below the source region 30. Although not shown, the body region 32 is in ohmic contact with the source contact electrode 70a in a cross-section different from FIG. 1.

The drift region 34 is an n-type region. The drift region 34 is disposed below the body region 32. The drift region 34 extends from a position in contact with the gate insulating film 24 in the first trench 22a to a position in contact with the gate insulating film 24 in the second trench 22b. The drift region 34 is separated from the source region 30 by the body region 32. The drift region 34 is distributed to a depth range below the bottom end of each trench 22. In other words, the drift region 34 is distributed to a depth that is deeper than the bottom end of the trenches 22. The drift region 34 covers the bottom portion of the first trench 22a and covers the bottom portion of the second trench 22b.

The drain region 36 are n-type regions. The drain region 36 has an n-type impurity concentration higher than that of the drift region 34. The drain region 36 is disposed below the drift region 34. The drain region 36 is exposed on the lower surface 12b of the semiconductor substrate 12. The drain region 36 is in ohmic contact with the lower electrode 72.

As shown in FIG. 1, in a depth range Db in which the body region 32 is disposed, a maximum value W_{F} of a distance W between the first trench 22a and the second trench 22b is less than 200 nm. The distance W is defined by a distance between the side surfaces of two adjacent trenches 22 facing in the x direction. In the present embodiment, since the width of each trench 22 increases toward the lower side, the maximum value W_{F} in the depth range Db is defined at the upper end portion of the body region 32. In addition, since the width of each trench 22 increases toward the lower side, the distance W_{T} between the first trench 22a and the second trench 22b at the upper surface 12a of the semiconductor substrate 12 is larger than the maximum value W_{F}.

Next, an operation of the semiconductor device 10 will be described. When the semiconductor device 10 is used, the semiconductor device 10, a load, and a power supply are connected in series. The load is, for example, a motor. A power supply voltage is applied to the series circuit of the semiconductor device 10 and the load. The power supply voltage is applied in a direction in which the drain side (i.e., the lower electrode 72) has a higher potential than the source side (i.e., the upper electrode 70) in the semiconductor device 10. To turn on the semiconductor device 10, the potential of the gate electrode 26 is increased to a potential higher than the gate threshold. In the process of increasing the potential of the gate electrode 26, first, areas of the body region 32 in contact with the gate insulating film 24 in the first trench 22a and the gate insulating film 24 in the second trench 22b are inverted to the n-type. In the present embodiment, the maximum value W _{F} of the distance W between the first trench 22a and the second trench 22b in the depth range Db in which the body region 32 is disposed (that is, the maximum value of the width of the body region 32) is less than 200 nm. That is, since the width of the body region 32 is sufficiently narrow, when the potential of the gate electrode 26 is further increased, the inversion layer expands due to the occurrence of the FinFET effect, and substantially the entire area of the body region 32 is inverted to the n-type. As a result, a channel is formed in substantially the entire area of the body region 32 between the first trench 22a and the second trench 22b. When the source region 30 and the drift region 34 are connected by the channel, electrons flow from the source region 30 to the drift region 34 via the channel. As a result, the semiconductor device 10 is turned on. To turn off the semiconductor device 10, the potential of the gate electrode 26 is made lower than the gate threshold. Thus, the channel formed in the body region 32 disappears, and the semiconductor device 10 is turned off.

As described above, in the semiconductor device 10 of the present embodiment, the maximum value W_{F} of the distance W between the first trench 22a and the second trench 22b in the depth range Db in which the body region 32 is disposed is less than 200 nm, which is sufficiently small to cause the FinFET effect. Therefore, the channel can be formed in substantially the entire area of the body region 32. As such, the semiconductor device 10 has a low channel resistance.

In addition, the distance W_{T} between the first trench 22a and the second trench 22b at the upper surface 12a of the semiconductor substrate 12 is larger than the maximum value W_{F}. That is, the source region 30 is exposed over a wide range on the upper surface 12a of the semiconductor substrate 12. Therefore, the contact area between the source region 30 and the upper electrode 70, in particular, the source contact electrode 70a can be sufficiently ensured. As such, the semiconductor device 10 has a low contact resistance.

As described above, according to the semiconductor device 10 of the present embodiment, low channel resistance and low contact resistance can be realized.

Next, a method for manufacturing the semiconductor device 10 will be described with reference to FIGS. 2 to 10. First, as shown in FIG. 2, a first substrate 60 including an n-type substrate 50, an n-type source region 30 disposed on the n-type substrate 50, a p-type body region 32 disposed on the source region 30, and an n-type drift region 34 disposed on the body region 32 is prepared. The first substrate 60 can be manufactured by, for example, forming the source region 30, the body region 32, and the drift region 34 on the n-type substrate 50 by combining known techniques appropriately such as epitaxial growth and ion implantation.

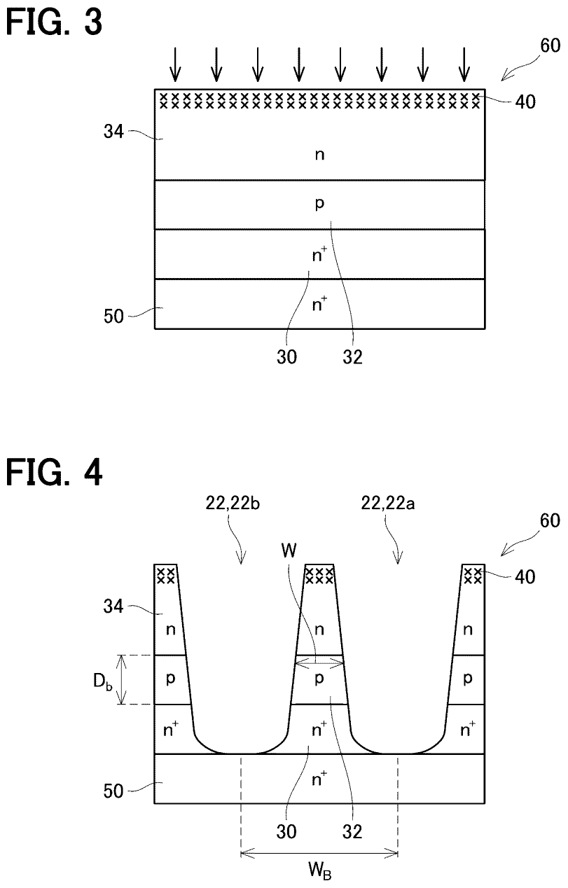

Next, as shown in FIG. 3, an amorphous layer 40 is formed in the vicinity of the upper surface of the drift region 34. In this case, for example, the upper surface of the drift region 34 is irradiated with argon atoms. As a result, the atomic arrangement in the vicinity of the upper surface of the drift region 34 is disordered, and the amorphous layer 40 is formed.

Next, as shown in FIG. 4, multiple trenches 22 are selectively formed in the upper surface of the drift region 34 by etching. Here, the trenches 22 are each formed to extend from the upper surface of the drift region 34 through the body region 32 and reach the vicinity of the bottom surface of the source region 30. The side surface of the trench 22 formed by the etching of the first substrate 60 is inclined in a direction in which the width of the upper end portion of the trench 22 is larger than the width of the bottom portion of the trench 22. That is, the trench 22 is formed such that the width thereof gradually decreases toward the lower side. Further, the trench 22 is formed such that the bottom surface thereof has a curved shape. In this process, each of the trenches 22 is formed such that the maximum value of the distance W between two adjacent trenches 22 (i.e., the first trench 22a and the second trench 22b) in the depth range Db in which the body region 32 is disposed is less than 200 nm. In addition, each of the trenches 22 is formed such that the distance W_{B} between the bottom portions of two adjacent trenches 22 is larger than the maximum value of the distance W.

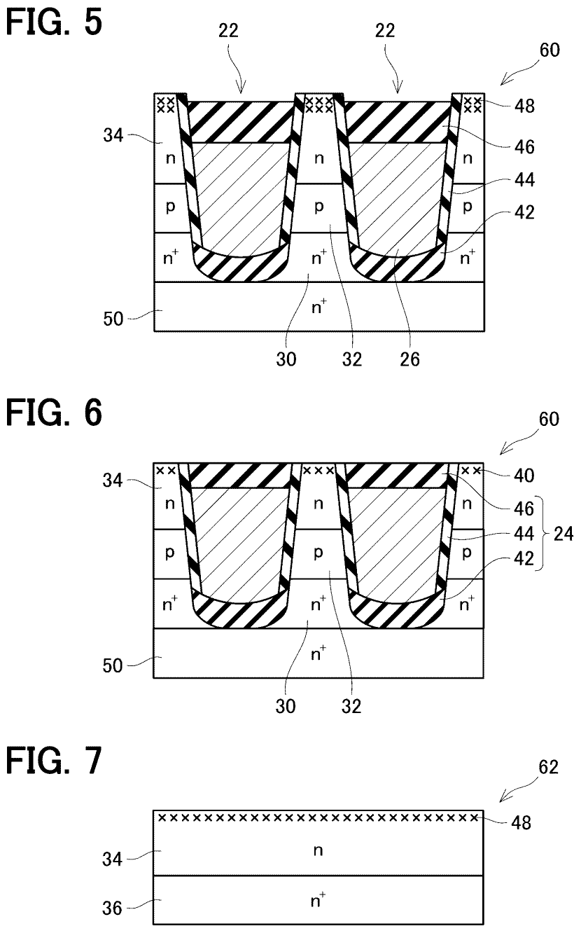

Next, as shown in FIG. 5, an insulating film 42 is formed so as to cover the bottom surface of each trench 22. The insulating film 42 is formed such that its upper end is located below the upper end of the source region 30. Next, an insulating film 44 is formed on the side surface of each trench 22. Thereafter, polysilicon is deposited inside each trench 22 to form the gate electrode 26. The gate electrode 26 is formed such that its upper end is located above the upper end of the body region 32. Next, an insulating film 46 is formed so as to cover the upper surface of the gate electrode 26.

Next, as shown in FIG. 6, the upper surface of the drift region 34 and the upper surface of the insulating film 46 are planarized so that the amorphous layer 40 remains, by using, for example, a chemical mechanical polishing (CMP) technique. The remaining insulating films 42, 44, and 46 form the gate insulating film 24.

Next, a second substrate 62 shown in FIG. 7 is prepared. The second substrate 62 includes an n-type drain region 36 and an n-type drift region 34 disposed on the drain region 36. For example, the second substrate 62 can be manufactured by performing epitaxial growth on an n-type substrate as the drain region 36 to form the drift region 34. Then, an amorphous layer 48 is formed in the vicinity of the upper surface of the drift region 34. The amorphous layer 48 can be formed by the similar process to the amorphous layer 40 shown in FIG. 3.

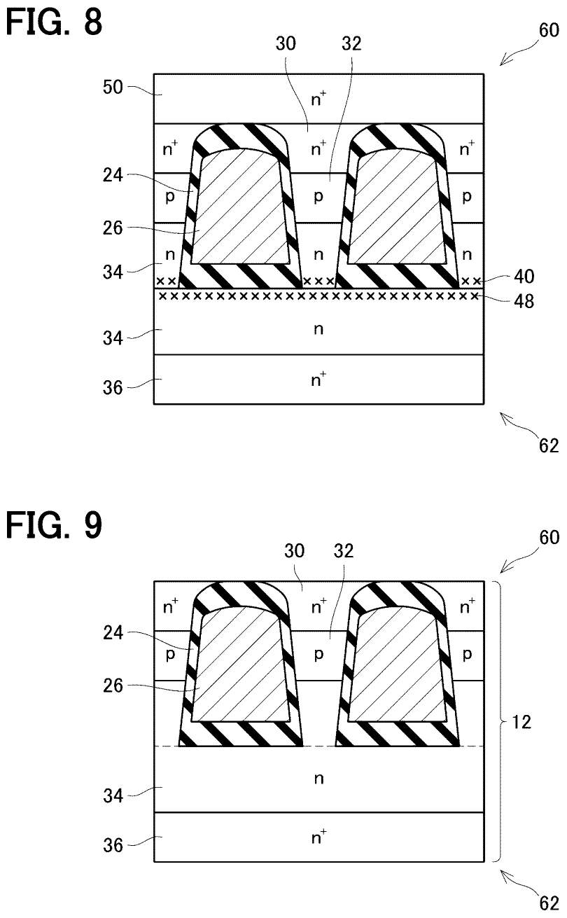

Next, as shown in FIG. 8, the first substrate 60 and the second substrate 62 are bonded to each other. In this case, a heat treatment at about 1000 degrees Celsius (° C.) is performed in a vacuum environment in a state where the first substrate 60 and the second substrate 62 are in contact with each other such that the amorphous layer 40 of the first substrate 60 and the amorphous layer 48 of the second substrate 62 face each other. As a result, the disordered atoms of the amorphous layers 40 and 48 flow in the direction in which they are aligned, and the amorphous layers 40 and 48 return to the crystalline state. In this process, the first substrate 60 and the second substrate 62 are bonded to each other. It should be noted that, in FIG. 8 and subsequent figures, the first substrate 60 shown in FIGS. 2 to 7 is illustrated upside down.

Next, as shown in FIG. 9, the n-type substrate 50 is removed. Specifically, the first substrate 60 is ground from the n-type substrate 50 side using, for example, the CMP technique so as to expose the source region 30 and the gate insulating film 24 (that is, the insulating film 42). The first substrate 60 and the second substrate 62 after the grinding become the semiconductor substrate 12.

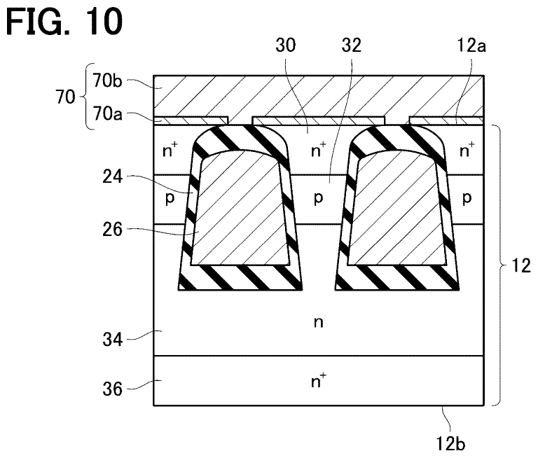

Next, as shown in FIG. 10, an upper electrode 70 is formed on an upper surface 12a of the semiconductor substrate 12 to be in contact with the source region 30. Specifically, after a source contact electrode 70a is formed so as to cover a range where the source region 30 is exposed, a source electrode 70b is formed so as to cover the source contact electrode 70a and the gate insulating film 24.

Thereafter, a lower electrode 72 is formed on a lower surface 12b of the semiconductor substrate 12. In this way, the semiconductor device 10 shown in FIG. 1 is produced.

In the manufacturing method described above, the trenches 22 are formed in the first substrate 60 such that the distance W_{B} between the first trench 22a and the second trench 22b at the bottoms of the first trench 22a and the second trench 22b is greater than the maximum value of the distance W between the first trench 22a and the second trench 22b in the depth range D_{b} in which the body region 32 is disposed. Then, the upper surface of the second substrate 62 formed with the amorphous layer 48 and the trench-formed surface of the first substrate 60 adjacent to the drift region 34 are bonded to each other. That is, the first substrate 60 in which the trenches 22 are formed is flipped over and bonded to the second substrate 62. Thereafter, the surface of the first substrate 60 opposite to the trench-formed surface, that is, the surface of the first substrate 60 bonded to the second substrate 62 is ground so as to expose the source region 30 and the gate insulating film 24 (that is, the insulating film 42) in the trench 22. Further, the upper electrode 70 is formed to be in contact with the exposed source region 30. As a result, the trenches 22 in which the distance between the first trench 22a and the second trench 22b at the position in contact with the upper electrode 70 is larger than the maximum value described above can be obtained. Here, the position in contact with the upper electrode 70 corresponds to the position that was the bottom portions of the first trench 22a and the second trench 22b. In the manufacturing method described above, since the two substrates 60 and 62 are prepared, it is possible to obtain the trench 22 in which the width of the lower portion is larger than the width of the upper portion, which has been difficult in a related art. As such, it is possible to ensure the contact area between the source region 30 and the upper electrode 70. In addition, the first trench 22a and the second trench 22b are formed so that the maximum value of the distance therebetween is less than 200 nm. As a result, it is possible to manufacture the semiconductor device 10 having a low channel resistance due to the FinFET effect and the low contact resistance.

The source region 30 is an example of a “first semiconductor region”, and the drift region 34 is an example of a “second semiconductor region”. The insulating films 42 and 44 are examples of a “first insulating film”, and the insulating film 46 is an example of a “second insulating film”.

In the embodiment described above, the side surface of the trench 22 is composed of the first side surface portion 23a and the second side surface portion 23b. However, the side surface of the trench 22 may be made of, for example, only the second side surface portion 23b. Further, in the embodiment described above, the distance between the trenches 22 reduces from the upper surface 12a of the semiconductor substrate 12 toward the lower side. However, the present disclosure is not limited to such a configuration. In the technology of the present disclosure, the shape of the side surface of the trench 22 is not particularly limited as long as the distance between the first trench 22a and the second trench 22b at the upper surface 12a of the semiconductor substrate 12, that is, the width of the source region 30 exposed between the first trench 22a and the second trench 22b is larger than the maximum value W_{F}.

In the embodiment described above, the source region 30 is in contact with the gate insulating film 24. However, the source region 30 may not be in contact with the gate insulating film 24. In the technique of the present disclosure, since the channel is formed in substantially the entire region of the body region 32, electrons flow even at a position away from the gate insulating film 24 in the body region 32. Therefore, even when the source region 30 is not in contact with the gate insulating film 24, the electrons can flow from the upper electrode 70 to the lower electrode 72 via the source region 30, the channel, the drift region 34, and the drain region 36.

In the embodiment described above, the semiconductor device 10 is exemplarily the MOSFET. However, the semiconductor device 10 may be an insulated gate bipolar transistor (IGBT). The structure of the IGBT can be obtained by changing the drain region 36 to a p-type region.

While only the selected exemplary embodiment(s) and example(s) have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment(s) and example(s) according to the present disclosure is provided for illustration only, and not for the purpose of limiting the disclosure as defined by the appended claims and their equivalents.

What is claimed is:

1. A trench gate semiconductor device, comprising:
a semiconductor substrate; and
a first trench provided in an upper surface of the semiconductor substrate;
a second trench provided in the upper surface of the semiconductor substrate and spaced apart from the first trench in a lateral direction;
a gate insulating film covering an inner surface of each of the first trench and the second trench;
a gate electrode disposed in each of the first trench and the second trench and insulated from the semiconductor substrate by the gate insulating film; and
an upper electrode covering the upper surface of the semiconductor substrate,
wherein the semiconductor substrate includes:
an n-type first semiconductor region that is disposed between the first trench and the second trench and in contact with the upper electrode;
a p-type body region that is disposed between the first trench and the second trench below the first semiconductor region, and extends from a position in contact with the gate insulating film in the first trench to a position in contact with the gate insulating film in the second trench; and
an n-type second semiconductor region that is disposed between the first trench and the second trench below the body region, extends from a position in contact with the gate insulating film in the first trench to a position in contact with the gate insulating film in the second trench, and is separated from the first semiconductor region by the body region,
wherein a maximum value of a distance between the first trench and the second trench in the lateral direction in a depth range in which the body region is disposed is less than 200 nm, and
wherein the distance between the first trench and the second trench at the upper surface of the semiconductor substrate is larger than the maximum value.

2. The trench gate semiconductor device according to claim 1, wherein
the distance between the first trench and the second trench decreases from the upper surface of the semiconductor substrate toward a lower side.

3. The trench gate semiconductor device according to claim 1, wherein
a width of each of the first trench and the second trench in the lateral direction increases towards a bottom end.

4. The trench gate semiconductor device according to claim 1, wherein
a side surface of each of the first trench and the second trench has a first surface portion connecting to the upper surface of the semiconductor substrate and a second surface portion extending from a lower end of the first surface portion,
the first surface portion is a curved surface, and
an angle defined between the first surface portion and the upper surface of the semiconductor substrate is smaller than an angle defined between the second surface portion and the upper surface of the semiconductor substrate.

5. A method for manufacturing a trench gate semiconductor device, the method comprising:
preparing a first substrate having an n-type first semiconductor region disposed on an upper surface of an n-type substrate, a p-type body region disposed on an upper surface of the first semiconductor region, and an n-type second semiconductor region disposed on an upper surface of the body region;
forming an amorphous layer in a vicinity of an upper surface of the second semiconductor region;
forming a first trench and a second trench each extending from the upper surface of the second semiconductor region and reaching the first semiconductor region, the first trench and the second trench being formed such that a maximum value of a distance between the first trench and the second trench in a lateral direction in a depth range in which the body region is disposed is less than 200 nm, and the distance between the first trench and the second trench at bottoms of the first trench and the second trench is larger than the maximum value;
forming a first insulating film covering an inner surface of each of the first trench and the second trench, a gate electrode disposed in each of the first trench and the second trench, and a second insulating film covering an upper surface of the gate electrode disposed in each of the first trench and the second trench;
planarizing the upper surface of the second semiconductor region and the upper surface of the second insulating film while remaining the amorphous layer;
preparing an n-type second substrate having an amorphous layer in a vicinity of an upper surface thereof;
bonding the first substrate and the second substrate so that the amorphous layer of the first substrate and the amorphous layer of the second substrate face each other;
grinding the first substrate from the n-type substrate side to expose the first semiconductor region and the first insulating film disposed in each of the first trench and the second trench; and
forming an electrode to be in contact with the first semiconductor region exposed by the grinding.
